(19) United States
(12) Patent Application Publication
(10) Pub. No.: US 2026/0212088 A1
(43) Pub. Date: Jul. 23, 2026

(54) APPARATUS AND METHOD FOR BIDIRECTIONAL DATA INTEGRATION

(71) Applicant: Neo7Bioscience, Inc., Dallas, TX (US)

(72) Inventor: John A. Catanzaro, Rockwall, TX (US)

(21) Appl. No.: 19/455,085

(22) Filed: Jan. 21, 2026

Related U.S. Application Data
(60) Provisional application No. 63/747,652, filed on Jan. 21, 2025.

(51) Int. Cl. G06F 30/27

(52) U.S. Cl. CPC G06F 30/27

(57) ABSTRACT

An apparatus and method for bidirectional data integration are described. The apparatus includes at least a processor and a memory communicatively connected to the at least a processor, wherein the memory contains instructions configuring the at least a processor to receive organoid data and omics data, generate integrated data by integrating the organoid data and the omics data bidirectionally, generate a disease pathway as a function of the integrated data, generate a peptide datum using a peptide machine-learning model as a function of the integrated data and the disease pathway, determine an absorption, distribution, metabolism, excretion, and toxicity (ADMET) datum as a function of the peptide datum and generate a user interface displaying the integrated data, the peptide datum and the ADMET datum on a user device.

### CROSS-REFERENCE TO RELATED APPLICATIONS

This application is a Non-provisional Application of U.S. Provisional Application No. 63/747,652 filed on Jan. 21, 2025, and entitled “APPARATUS AND METHOD FOR BIDIRECTIONAL DATA INTEGRATION” the entirety of which is incorporated by reference in its entirety.

### FIELD OF THE INVENTION

The present invention generally relates to the field of data processing. In particular, the present invention is directed to an apparatus and method for bidirectional data integration.

### BACKGROUND

Peptide-based therapeutics have emerged as a promising class of drugs due to their high specificity, efficacy, and relative safety compared to small molecules or biologics. Peptides can be designed to mimic or disrupt protein-protein interactions, modulate signaling pathways, and target molecular mechanisms underlying various diseases. Despite their potential, the development of therapeutic peptides faces significant challenges, including optimizing binding affinity, stability, and pharmacokinetic properties, as well as minimizing toxicity and immunogenicity.

### SUMMARY OF THE DISCLOSURE

In an aspect, an apparatus for bidirectional data integration, the apparatus comprising at least a processor; and a memory communicatively connected to the at least a processor, wherein the memory contains instructions configuring the at least a processor to receive organoid data and omics data; generate integrated data by integrating the organoid data and the omics data bidirectionally, wherein integrating the organoid data and the omics data bidirectionally comprises forward integration to correlate at least an organoid-derived parameter of the organoid data to molecular changes of the omics data; and reverse integration to correlate at least an omics-derived parameter of the omics data to therapeutic agents of the organoid data; generate a disease pathway as a function of the integrated data; generate a peptide datum using a peptide machine-learning model as a function of the integrated data and the disease pathway; determine an absorption, distribution, metabolism, excretion, and toxicity (ADMET) datum as a function of the peptide datum; and generate a user interface displaying the integrated data, the peptide datum and the ADMET datum on a user device.

In yet another non-limiting aspect, A method for bidirectional data integration, the method comprising receiving, using at least a processor, organoid data and omics data; generating, using the at least a processor, integrated data by integrating the organoid data and the omics data bidirectionally, wherein integrating the organoid data and the omics data bidirectionally comprises forward integration to correlate at least an organoid-derived parameter of the organoid data to molecular changes of the omics data; and reverse integration to correlate at least an omics-derived parameter of the omics data to therapeutic agents of the organoid data; generating, using the at least a processor, a disease pathway as a function of the integrated data; generating, using the at least a processor, a peptide datum using a peptide machine-learning model as a function of the integrated data and the disease pathway; determining, using the at least a processor, an absorption, distribution, metabolism, excretion, and toxicity (ADMET) datum as a function of the peptide datum; and generating, using the at least a processor, a user interface displaying the integrated data, the peptide datum and the ADMET datum on a user device.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 illustrates a block diagram of an exemplary apparatus for bidirectional data integration;

FIG. 2 illustrates a block diagram of an exemplary system for OTO-BDI with ADMET integration;

FIG. 3 illustrates a configuration of an exemplary user interface on a user device;

FIG. 4 illustrates a block diagram of an exemplary machine-learning module;

FIG. 5 illustrates a diagram of an exemplary neural network;

FIG. 6 illustrates a block diagram of an exemplary node in a neural network;

FIG. 7 illustrates a flow diagram of an exemplary method for bidirectional data integration; and

FIG. 8 illustrates a block diagram of a computing system that can be used to implement any one or more of the methodologies disclosed herein and any one or more portions thereof. The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

At a high level, aspects of the present disclosure are directed to apparatuses and methods for bidirectional data integration. The apparatus includes at least a processor and a memory communicatively connected to the at least a processor, wherein the memory contains instructions configuring the at least a processor to receive organoid data and omics data, generate integrated data by integrating the organoid data and the omics data bidirectionally, wherein integrating the organoid data and the omics data bidirectionally comprises forward integration to correlate at least an organoid-derived parameter of the organoid data to molecular changes of the omics data and reverse integration to correlate at least an omics-derived parameter of the omics data to therapeutic agents of the organoid data, generate a disease pathway as a function of the integrated data, generate a peptide datum using a machine-learning model as a function of the integrated data and the disease pathway, determine an absorption, distribution, metabolism, excretion, and toxicity (ADMET) datum as a function of the peptide datum and generate a user interface displaying the integrated data, the peptide datum and the ADMET datum on a user device. Exemplary embodiments illustrating aspects of the present disclosure are described below in the context of several specific examples.

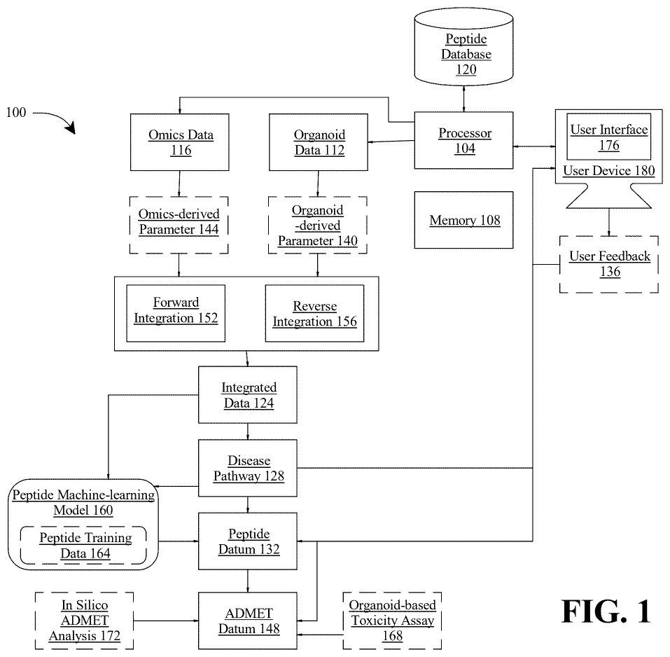

Referring now to FIG. 1, an exemplary embodiment of an apparatus 100 for bidirectional data integration is illustrated. Apparatus 100 includes at least a processor 104. Processor 104 may include, without limitation, any processor described in this disclosure. Processor 104 may be included in a computing device. Processor 104 may include any computing device as described in this disclosure, including without limitation a microcontroller, microprocessor, digital signal processor (DSP) and/or system on a chip (SoC) as described in this disclosure. Processor 104 may include, be included in, and/or communicate with a mobile device such as a mobile telephone or smartphone. Processor 104 may include a single computing device operating independently, or may include two or more computing device operating in concert, in parallel, sequentially or the like; two or more computing devices may be included together in a single computing device or in two or more computing devices. Processor 104 may interface or communicate with one or more additional devices as described below in further detail via a network interface device. Network interface device may be utilized for connecting processor 104 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Processor 104 may include but is not limited to, for example, a computing device or cluster of computing devices in a first location and a second computing device or cluster of computing devices in a second location. Processor 104 may include one or more computing devices dedicated to data storage, security, distribution of traffic for load balancing, and the like. Processor 104 may distribute one or more computing tasks as described below across a plurality of computing devices of computing device, which may operate in parallel, in series, redundantly, or in any other manner used for distribution of tasks or memory between computing devices. Processor 104 may be implemented, as a non-limiting example, using a “shared nothing” architecture.

With continued reference to FIG. 1, processor 104 may be designed and/or configured to perform any method, method step, or sequence of method steps in any embodiment described in this disclosure, in any order and with any degree of repetition. For instance, processor 104 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Processor 104 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, apparatus 100 includes a memory 108 communicatively connected to processor 104. For the purposes of this disclosure, “communicatively connected” means connected by way of a connection, attachment or linkage between two or more relata which allows for reception and/or transmittance of information therebetween. For example, and without limitation, this connection may be wired or wireless, direct or indirect, and between two or more components, circuits, devices, systems, and the like, which allows for reception and/or transmittance of data and/or signal(s) therebetween. Data and/or signals therebetween may include, without limitation, electrical, electromagnetic, magnetic, video, audio, radio and microwave data and/or signals, combinations thereof, and the like, among others. A communicative connection may be achieved, for example and without limitation, through wired or wireless electronic, digital or analog, communication, either directly or by way of one or more intervening devices or components. Further, communicative connection may include electrically coupling or connecting at least an output of one device, component, or circuit to at least an input of another device, component, or circuit. For example, and without limitation, via a bus or other facility for intercommunication between elements of a computing device. Communicative connecting may also include indirect connections via, for example and without limitation, wireless connection, radio communication, low power wide area network, optical communication, magnetic, capacitive, or optical coupling, and the like. In some instances, the terminology “communicatively coupled” may be used in place of communicatively connected in this disclosure.

With continued reference to FIG. 1, memory 108 contains instructions configuring processor 104 to receive organoid data 112 and omics data 116. For the purposes of this disclosure, “organoid data” is data derived from organoid cultures. In some embodiments, organoid cultures may be three-dimensional, in vitro models that mimic the structure and function of specific tissues or organs. As a non-limiting example, organoid data 112 may include capture live imaging, multi-omics data, and phenotypic changes in organoid cultures. In some embodiments, organoid data 112 may include information of primary cells, organoids, immune cells, and the like that is used for organ-on-a-chip. Multi-omics data may include data such as variants and DSBs, RNA variants such as frameshifts and R-loops, HLA data including neoantigen binding, and proteome data including misfolds and oxidized residues. aHI data may include GTT-specific scans that may detect mRNA integrations, CRISPR mosaics, germline drifts via in silico mapping including for example ViFi and CRISPOR analogs. aHI data may include pathway mapping which may rank enrichments for indication specific insights. aHI data may include dynamic simulations including ODE/PBD models that predict harm progression and efficacy of mitigation strategies. aHI data may include blood and urine synergy including systemic (blood cfDNA) and excreted urine proteome signals for non-invasive monitoring. aHI data and other sources of data may be collected and shared via APIs and source tagging from biological samples such as blood and urine. The organ-on-a-chip disclosed herein is further described below. For the purposes of this disclosure, “omics data” is data related to various disciplines in biology. As a non-limiting example, omics data 116 may include process genomic, transcriptomic, and proteomic data for predictive modeling. Omics data 116 may include RNA Expression Variant Instability Surveillance (REViSS) data. REVISS data may combine transcriptomics, spike-related synthetic signatures, and oncogenic potential scoring. This may utilize hybrid intelligence (aHI) to quantify and map systemic molecular instabilities. This may be used to stratify clinical risk post-vaccine, post-COVID, or chronic immune syndromes. REVISS data may include a REVISS score which may quantify signal-based molecular aberrations in patient samples. A REVISS score may integrate unfavorable gene expression, synthetic RNA contamination, and oncogenic potential. A REVISS score may provide a personalized molecular disruption index. REVISS data may be utilized to identify aberrations in immune regulation including cytokine signaling, antigen presentation, and TLR balance. REVISS data may identify core hallmark expression genes and proteins involved in homeostatic regulation. REVISS data may identify inflammatory resolution proteins that may misfire, including NF-kB, STAT3, and IL6. REVISS data may identify structural signaling collagens and laminins which show downregulation or mistranslation such as fibrous clots and tissue strands. REViSS data may identify ribosomal instability which contributes to mistranslation and misfolding. REViSS data may identify dysregulation of TP53, BRCA 1/2, RB1 and other key regulators. REVISS data may identify activation of proliferation and migration such as MYC, KRAS, and BCL2. REViSS data may identify oncogenic role-switching due to mistranslation. REVISS data may identify spike-linked synthetic elements and contaminants. REVISS data may aid in identifying signal disruption which precedes symptomatic disease. REVISS data may aid in identifying immune deregulation and oncogene instability which initiate chronic disease cascades. REVISS data may aid in the generation of precision and personalized peptides which offer selective and restorative correction. REVISS data may aid in designing personalized peptides to correct faulty molecular singles and direct spike mitigation. REVISS data may use hybrid intelligence (aHI) and omics data 116 for real-time surveillance. REVISS data may target immune recalibration and oncogene suppression and restore immune, transcriptional, and mitochondrial balance. This may aid in mapping molecular disorders in real time and enable signal-specific curated interventions. REVISS data may include genomic instability multiplier data (GIM). “Genomic instability multiplier data” as used in this disclosure is a quantitative surveillance construct that measures how multiple destabilizing molecular signals interact to amply genomic and transcriptomic instability beyond any single abnormality alone. GIM models the non-linear compounding effect of concurrent disruptions across DNA integrity, RNA fidelity, chromatin regulation, mitochondrial signaling, and immune stress pathways to produce a multiplier effect on disease risk, progression, and therapeutic resistance. GIM may include components such as but not limited to:
DNA-level instability: strand breaks, replication stress, CNVs, translocations
RNA instability: aberrant splicing, chimeric transcripts, frameshifts, persistence of foreign or dysregulated RNA species
Epigenetic dysregulation: chromatin accessibility shifts, methylation errors, histone imbalance
Mitochondrial-genomic crosstalk failure: mtDNA stress signaling, 12S/16S rRNA dysregulation, ROS amplification
Immune-inflammatory pressure: interferon exhaustion, chronic innate activation, checkpoint distortion

Each domain alone may be clinically silent or subthreshold. When combined, they multiply system instability accelerating: oncogenic transformation; neurodegeneration; immune collapse or autoimmunity; and treatment failure and relapse. GIM functions as a derived index layered on top of RNA-seq and multi-omic inputs, converting distributed molecular noise into a single instability acceleration score used for: early risk stratification, longitudinal surveillance, therapy timing and personalization; and prediction of rapid phase transitions (e.g. stable→unstable states). GIM aids in quantifying how close a system is to losing control.

With continued reference to FIG. 1, in some embodiments, receiving organoid data 112 and omics data 116 may include normalizing the organoid data 112 and the omics data 116 to remove noise, batch effects and biases. In some embodiments, processor 104 may normalize datasets to remove noise, batch effects, and biases using tools like DESeq2, MaxQuant. “DESeq2” is a software package designed for the analysis of count-based RNA sequencing data. DESeq2 can normalize raw count data, adjusting for differences in sequencing depth and other systematic biases, thereby enabling accurate detection of differential gene expression across experimental conditions. “MaxQuant” is a computational platform for analyzing mass spectrometry-based proteomics data. MaxQuant can perform peak detection, quantification, and normalization of protein abundances, correcting for technical variations and enhancing the reliability of protein expression measurements.

With continued reference to FIG. 1, in some embodiments, apparatus 100 may include a peptide database 120. As used in this disclosure, “peptide database” is a data structure configured to store data associated with peptides. As a non-limiting example, peptide database 120 may store omics data 116, organoid data 112, integrated data 124, disease pathway 128, peptide datum 132, user feedback 136, organoid-derived parameter 140, omics-derived parameter 144, toxicity, ADMET datum 148, and the like. In one or more embodiments, peptide database 120 may include inputted or calculated information and datum related to peptide datum 132. In some embodiments, a datum history may be stored in peptide database 120. As a non-limiting example, the datum history may include real-time and/or previous inputted data related to peptide datum 132. As a non-limiting example, peptide database 120 may include instructions from a user, who may be an expert user, a past user in embodiments disclosed herein, or the like, where the instructions may include examples of the data related to peptide datum 132.

With continued reference to FIG. 1, in some embodiments, processor 104 may be communicatively connected with peptide database 120. For example, and without limitation, in some cases, peptide database 120 may be local to processor 104. In another example, and without limitation, peptide database 120 may be remote to processor 104 and communicative with processor 104 by way of one or more networks. The network may include, but is not limited to, a cloud network, a mesh network, and the like. By way of example, a “cloud-based” system can refer to a system which includes software and/or data which is stored, managed, and/or processed on a network of remote servers hosted in the “cloud,” e.g., via the Internet, rather than on local severs or personal computers. A “mesh network” as used in this disclosure is a local network topology in which the infrastructure processor 104 connect directly, dynamically, and non-hierarchically to as many other computing devices as possible. A “network topology” as used in this disclosure is an arrangement of elements of a communication network. The network may use an immutable sequential listing to securely store peptide database 120. An “immutable sequential listing,” as used in this disclosure, is a data structure that places data entries in a fixed sequential arrangement, such as a temporal sequence of entries and/or blocks thereof, where the sequential arrangement, once established, cannot be altered or reordered. An immutable sequential listing may be, include and/or implement an immutable ledger, where data entries that have been posted to the immutable sequential listing cannot be altered.

With continued reference to FIG. 1, in some embodiments, peptide database 120 may be implemented, without limitation, as a relational database, a key-value retrieval database such as a NOSQL database, or any other format or structure for use as a database that a person skilled in the art would recognize as suitable upon review of the entirety of this disclosure. Database may alternatively or additionally be implemented using a distributed data storage protocol and/or data structure, such as a distributed hash table or the like. Database may include a plurality of data entries and/or records as described above. Data entries in a database may be flagged with or linked to one or more additional elements of information, which may be reflected in data entry cells and/or in linked tables such as tables related by one or more indices in a relational database. Persons skilled in the art, upon reviewing the entirety of this disclosure, will be aware of various ways in which data entries in a database may store, retrieve, organize, and/or reflect data and/or records as used herein, as well as categories and/or populations of data consistently with this disclosure.

With continued reference to FIG. 1, in some embodiments, receiving organoid data 112 and omics data 116 may include extracting at least an organoid-derived parameter 140 and the at least an omics-derived parameter 144 as a function of the organoid data 112 and the omics data 116. For the purposes of this disclosure, an “organoid-derived parameter” is a quantitative or qualitative value obtained from organoid data. In some embodiments, organoid-derived parameter 140 may characterize a specific aspect of the organoid's structure, function, or response under study. As a non-limiting example, organoid-derived parameter 140 may include organoid behavior (e.g., cellular response, protein expression), and the like. As another non-limiting example, organoid-derived parameters 140 may include changes in gene expression levels, protein production rates, cellular viability metrics, morphological features such as size or shape, and functional markers such as electrical activity or secretion levels. For the purposes of this disclosure, an “omics-derived parameter” is a measurable value derived from omics data. In some embodiments, omics-derived parameter 144 may represent a molecular characteristic or interaction within a biological system. As a non-limiting example, omics-derived parameters 144 may include expression level of a specific gene, the abundance of a protein, the presence or frequency of genetic variants, or the activity of a molecular pathway inferred from multi-omics integration.

With continued reference to FIG. 1, memory 108 contains instructions configuring processor 104 to generate integrated data 124 by integrating organoid data 112 and omics data 116 bidirectionally, wherein the integration includes forward integration 152 to correlate at least an organoid-derived parameter 140 of the organoid data 112 to molecular changes of the omics data 116 and reverse integration 156 to correlate at least an omics-derived parameter 144 of the omics data 116 to therapeutic agents of the organoid data 112. For the purposes of this disclosure, “integrated data” is data resulting from the bidirectional correlation of organoid data and omics data. In some embodiments, integrated data 124 may represent a comprehensive dataset that combines insights from organoid-derived parameters with omics-derived parameters, such as molecular profiles or pathway activations. In some embodiments, integrated data 124 may provide a unified framework for understanding the relationships between organoid behavior and underlying molecular mechanisms, facilitating the identification of therapeutic targets and the evaluation of potential interventions. For the purposes of this disclosure, “forward integration” is a data analysis process wherein organoid-derived parameters are mapped and correlated to omics data. For the purposes of this disclosure, “reverse integration” is a data analysis process in which omics-derived parameters are mapped and correlated to organoid models. In some embodiments, forward integration 152 may extract organoid-derived data (e.g., changes in gene expression) and correlate them with molecular pathways identified from omics data 116. In some embodiments, reverse integration 156 may use OMICS predictions to identify potential peptide targets and guide experimental validation in organoid models.

With continued reference to FIG. 1, memory 108 contains instructions configuring processor 104 to generate a disease pathway 128 as a function of integrated data 124. In some embodiments, processor 104 may identify disease pathways 128 or molecular dysfunctions to target with peptides. For the purposes of this disclosure, a “disease pathway” is a sequence of molecular interactions, biological processes, or cellular mechanisms that contribute to a pathological condition. A disease pathway may include altered gene expression patterns, dysfunctional protein interactions, disrupted signaling cascades, or metabolic abnormalities identified through the analysis of integrated data. Disease pathways provide a framework for understanding the underlying biological mechanisms of a disease and serve as critical targets for the development of therapeutic interventions, such as peptide-based treatments.

With continued reference to FIG. 1, memory 108 contains instructions configuring processor 104 to generate a peptide datum 132 using a peptide machine-learning model 160 as a function of integrated data 124 and a disease pathway 128. In some embodiments, processor 104 may design peptides (peptide datum 132) using AI tools, focusing on improving binding affinity, stability, and therapeutic efficacy. For the purposes of this disclosure, a “peptide datum” is a data element that represents the design, structure, properties, or function of a peptide. In a non-limiting example, peptide datum 132 may include the amino acid sequence, predicted or measured binding affinity to a target molecule, structural stability under physiological conditions, pharmacokinetic properties, and therapeutic efficacy.

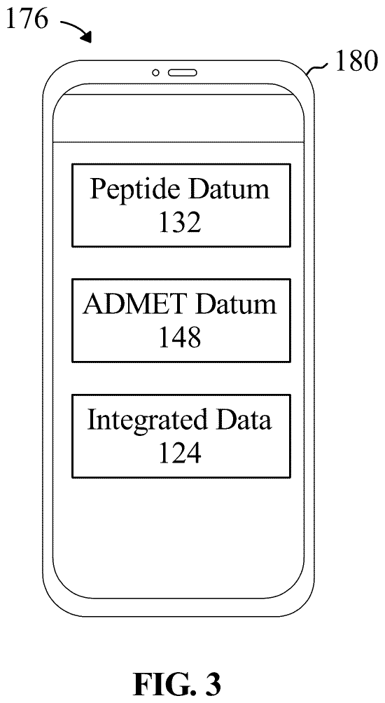

With continued reference to FIG. 1, in some embodiments, generating peptide datum 132 may include generating the peptide datum 132 as a function of affinity, stability, and therapeutic efficacy. In a non-limiting example, generating peptide datum 132 may include evaluating previously engineered peptides for a specific disease models, analyzing their molecular or protein pathway target sensitivity, specificity, and simulation affinity. In some embodiments, peptide datum 132 may include peptides with sequence or scaffolding modifications or reconfigurations to optimize the molecule's accuracy and efficacy. In some embodiments, generating peptide datum 132 may include generating peptide training data 164, wherein the peptide training data 164 may include exemplary integrated data and exemplary disease pathways correlated to exemplary peptide data, training a peptide machine-learning model 160 using the peptide training data 164 and generating the peptide datum 132 using the trained peptide machine-learning model 160. In some embodiments, processor 104 may be configured to generate peptide training data 164. In some embodiments, peptide training data 164 may include exemplary disease models (exemplary disease pathways) correlated to previously engineered peptides. In a non-limiting example, previously engineered peptides may include peptides that were modified or reconfigured their sequence or scaffolding to optimize the molecule's accuracy and efficacy. In some embodiments, peptide training data 164 may be stored in peptide database 120. In some embodiments, peptide training data 164 may be received from one or more users, peptide database 120, external computing devices, and/or previous iterations of processing. As a non-limiting example, peptide training data 164 may include instructions from a user, who may be an expert user, a past user in embodiments disclosed herein, or the like, which may be stored in memory and/or stored in peptide database 120, where the instructions may include labeling of training examples. In some embodiments, peptide training data 164 may be updated iteratively on a feedback loop. As a non-limiting example, processor 104 may update peptide training data 164 iteratively through a feedback loop as a function of organoid-derived parameter 140, omics-derived parameter 144, disease pathway 128, organoid data 112 and omics data 116, user feedback 136, or the like. In some embodiments, processor 104 may be configured to generate a peptide machine-learning model 160. In a non-limiting example, generating peptide machine-learning model 160 may include training, retraining, or fine-tuning peptide machine-learning model 160 using peptide training data 164 or updated peptide training data 164. In some embodiments, processor 104 may be configured to determine peptide datum 132 using peptide machine-learning model 160 (i.e. trained or updated peptide machine-learning model 160). In some embodiments, user, patient or any data (e.g., organoid data 112 and omics data 116) described herein may be classified to a cohort using a cohort classifier. Cohort classifier may be consistent with any classifier discussed in this disclosure. Cohort classifier may be trained on cohort training data, wherein the cohort training data may include data correlated to cohorts. In some embodiments, a user, patient or any data (e.g., organoid data 112 and omics data 116) may be classified to a cohort and processor 104 may determine peptide datum 132 based on the cohort using a machine-learning module as described in detail with respect to FIG. 3 and the resulting output may be used to update peptide training data 164. In some embodiments, generating training data and training machine-learning models may be simultaneous.

With continued reference to FIG. 1, memory 108 contains instructions configuring processor 104 to determine an absorption, distribution, metabolism, excretion, and toxicity (ADMET) datum 148 as a function of peptide datum 132. For the purposes of this disclosure, an “absorption, distribution, metabolism, excretion, and toxicity datum” is a data element that represents the predicted or experimentally measured pharmacokinetic and toxicological properties of a peptide. As a non-limiting example, ADMET datum 148 may include metrics or parameters characterizing the peptide's ability to be absorbed into the bloodstream, distributed to target tissues, metabolized by biological systems, excreted from the body, and its potential for toxic effects on cells, tissues, or organs. In some embodiments, processor 104 may use ADMET prediction tools to simulate pharmacokinetics (absorption, distribution, metabolism, excretion) and toxicity profiles of peptides (peptide datum 132). In some embodiments, processor 104 may assess toxicity using organoid-based toxicity assays 168 to ensure safety before in vivo testing. For the purposes of this disclosure, “organoid-based toxicity assays” are experimental methods that evaluates the toxicological effects of a substance. In some embodiments, processor 104 may refine peptides based on ADMET results (ADMET datum 148) to ensure optimal therapeutic properties. In some embodiments, processor 104 may be configured for peptide testing to expose organoids to engineered peptides and monitor for molecular correction or disease pathway reversal. In some embodiments, processor 104 may incorporate organoid responses to further refine peptide designs and improve therapeutic efficacy. In some embodiments, processor 104 may automate cycles of model optimization based on continuous organoid-omics feedback, ADMET analysis, and peptide testing. In some embodiments, processor 104 may adjust peptide sequences, dosage, and delivery methods to ensure therapeutic success and safety.

With continued reference to FIG. 1, in some embodiments, determining ADMET datum 148 may include analyzing an organ-on-a-chip as a function of peptide datum 132. For the purposes of this disclosure, an “organ-on-a-chip” is a microfluidic device that recreates the microarchitecture, functions, and dynamic behaviors of living human organs or tissues in vitro. Organ-on-a-chip systems can be engineered to replicate the physical, chemical, and mechanical properties of the organ they model. In a non-limiting example, organ-on-a-chip may be modeled to include integrated data 124 and/or disease pathway 128. Organ-on-a-chip can be used to study biological processes, disease mechanisms, and drug responses. In a non-limiting example, organ-on-a-chip may be used to study the effect of peptide datum 132 and to determine disease pathway 128 and/or ADMET datum 148. In some embodiments, processor 104 may evaluate critical functional endpoints such as biomarkers of tissue health (e.g., indicators of cellular damage or stress), apparent permeability (Papp, which measures the movement of substances across tissue barriers), cytokine release (which indicates immune response), and metabolomics (the study of metabolites that reflect biochemical activity within the tissue) of effluent from an organ-on-a chip and determine ADMET datum 148 based on the analysis of the effluent. In some embodiments, processor 104 may analyze images of organ-on-a-chip or visual representations of cells and tissues within the organ-on-a-chip. In a non-limiting example, processor 104 may analyze images for cell morphology (shape and structure), protein expression (indicators of cellular activity and identity), and behavior, such as migration (movement of cells in response to stimuli) using various imaging modalities. For example, and without limitation, imaging modalities may include brightfield microscopy, phase contrast, widefield fluorescence, confocal microscopy, multiphoton microscopy, and scanning electron microscopy, and the like. In some embodiments, processor 104 may use machine vision module, image processing module, and the like to analyze images of organ-on-a-chip or visual representations of cells and tissues within the organ-on-a-chip and determine ADMET datum 148 based on the analysis. In some embodiments, processor 104 may determine ADMET datum 148 and/or disease pathway 128 by comparing information related to organ-on-a-chip to information related to in vitro tissues. In a non-limiting example, processor 104 may assess similarity between the information or identify genetic differences between healthy and diseased states.

With continued reference to FIG. 1, in some embodiments, determining ADMET datum 148 may include receiving user feedback 136 for displayed peptide datum 132 and the ADMET datum 148 and updating the peptide datum 132 and the ADMET datum 148 as a function of the user feedback 136. For the purposes of this disclosure, “user feedback” is an input provided by a user related to displayed data. For the purposes of this disclosure, a “user” is an individual, entity or group that uses an apparatus 100. As a non-limiting example, user may include researcher, clinician, and the like. In some embodiments, processor 104 may be configured to update peptide training data 164 using user feedback 136. A peptide machine-learning model 160 may use user feedback 136 to update its training data, thereby improving its performance, speed, and accuracy. In embodiments, the peptide machine-learning model 160 may be iteratively updated using input and output results of past iterations of the peptide machine-learning model 160. The peptide machine-learning model 160 may then be iteratively retrained using the updated peptide training data 164. For instance, and without limitation, peptide machine-learning model 160 may be trained using a first training data from, for example, and without limitation, training data from user feedback 136 or database. The peptide machine-learning model 160 may then be updated by using previous inputs and outputs from the peptide machine-learning model 160 as second set of training data to then retrain a newer iteration of peptide machine-learning model 160. This process of updating the peptide machine-learning model 160 and its associated training data may be continuously done to create subsequent peptide machine-learning model 160 to improve the speed and accuracy of the peptide machine-learning model 160. When users interact with the software, their actions, preferences, and feedback provide valuable information that can be used to refine and enhance the model. This user feedback 136 may be collected and incorporated into the training data, allowing the machine-learning model to learn from real-world interactions and adapt its predictions accordingly. By continually incorporating user feedback 136, the model becomes more responsive to user needs and preferences, capturing evolving trends and patterns. This iterative process of updating the training data with user feedback 136 enables the machine-learning model to deliver more personalized and relevant results, ultimately enhancing the overall user experience. The discussion within this paragraph may apply to both the peptide machine-learning model 160 and any other machine-learning model/classifier discussed herein. Incorporating the user feedback 136 may include updating the training data by removing or adding correlations of data to a path or resources as indicated by the user feedback 136. Any machine-learning model as described herein may have the training data updated based on such feedback or data gathered using any method described herein. For example, when correlations in training data are based on outdated information, a web crawler may update such correlations based on more recent resources and information.

With continued reference to FIG. 1, processor 104 may use user feedback 136 to train the machine-learning models and/or classifiers described above. For example, machine-learning models and/or classifiers may be trained using past inputs and outputs of the machine-learning model. In some embodiments, if user feedback 136 indicates that an output of machine-learning models and/or classifiers was “unfavorable,” then that output and the corresponding input may be removed from peptide training data 164 used to train peptide machine-learning models 160 and/or classifiers, and/or may be replaced with a value entered by, e.g., another value that represents an ideal output given the input the machine-learning model originally received, permitting use in retraining, and adding to training data; in either case, machine-learning models may be retrained with modified training data as described in further detail below.

With continued reference to FIG. 1, in some embodiments, determining ADMET datum 148 may include updating peptide datum 132 as a function of the ADMET datum 148. In some embodiments, determining ADMET datum 148 may include conducting in silico ADMET analysis 172 to simulate pharmacokinetics and toxicity profiles of the peptide datum 132. For the purposes of this disclosure, “silico ADMET analysis” is a computational method for predicting the absorption, distribution, metabolism, excretion, and toxicity (ADMET) properties of a substance, such as a therapeutic peptide, using mathematical models, simulations, or machine-learning algorithms. In silico ADMET analysis 172 may leverage chemical structure data, physicochemical properties, and biological interaction models to simulate how the peptide behaves within a biological system. In silico ADMET analysis 172 may provide insights into pharmacokinetic parameters, such as bioavailability, tissue distribution, and metabolic stability, as well as toxicity risks, such as hepatotoxicity or cardiotoxicity.

With continued reference to FIG. 1, in some embodiments, determining ADMET datum 148 may include assessing toxicity of peptide datum 132 using organoid-based toxicity assays 168. In some embodiments, determining ADMET datum 148 may include optimizing peptide datum 132 as a function of the ADMET datum 148 and the toxicity of the peptide datum 132. For the purposes of this disclosure, “toxicity” is a degree to which a substance causes adverse effects on biological systems. Toxicity may manifest through mechanisms such as cytotoxicity, genotoxicity, or disruption of normal physiological functions. In some embodiments, toxicity may be assessed by evaluating metrics such as cell viability, apoptosis, necrosis, alterations in gene or protein expression, and functional impairments within biological models.

With continued reference to FIG. 1, memory 108 contains instructions configuring processor 104 to generate a user interface 176 displaying integrated data 124, peptide datum 132 and ADMET datum 148 on a user device 180. For the purposes of this disclosure, a “user device” is any device a user use to input data. As a non-limiting example, user device 180 may include a laptop, desktop, tablet, mobile phone, smart phone, smart watch, kiosk, screen, smart headset, or things of the like. In some embodiments, user device 180 may include an interface configured to receive inputs from user. In some embodiments, user may manually input any data into apparatus 100 using user device 180. In some embodiments, user may have a capability to process, store or transmit any information independently.

With continued reference to FIG. 1, for the purposes of this disclosure, a “user interface” is a means by which a user and a computer system interact; for example through the use of input devices and software. A user interface 176 may include a graphical user interface (GUI), command line interface (CLI), menu-driven user interface, touch user interface, voice user interface (VUI), form-based user interface, any combination thereof and the like. In some embodiments, user interface 176 may operate on and/or be communicatively connected to a decentralized platform, metaverse, and/or a decentralized exchange platform associated with the user. For example, a user may interact with user interface in virtual reality. In some embodiments, a user may interact with the use interface using a computing device distinct from and communicatively connected to at least a processor 104. For example, a smart phone, smart, tablet, or laptop operated by a user. In an embodiment, user interface 176 may include a graphical user interface. A “graphical user interface,” as used herein, is a graphical form of user interface that allows users to interact with electronic devices. In some embodiments, GUI may include icons, menus, other visual indicators or representations (graphics), audio indicators such as primary notation, and display information and related user controls. A menu may contain a list of choices and may allow users to select one from them. A menu bar may be displayed horizontally across the screen such as pull-down menu. When any option is clicked in this menu, then the pull-down menu may appear. A menu may include a context menu that appears only when the user performs a specific action. An example of this is pressing the right mouse button. When this is done, a menu may appear under the cursor. Files, programs, web pages and the like may be represented using a small picture in a graphical user interface. For example, links to decentralized platforms as described in this disclosure may be incorporated using icons. Using an icon may be a fast way to open documents, run programs etc. because clicking on them yields instant access.

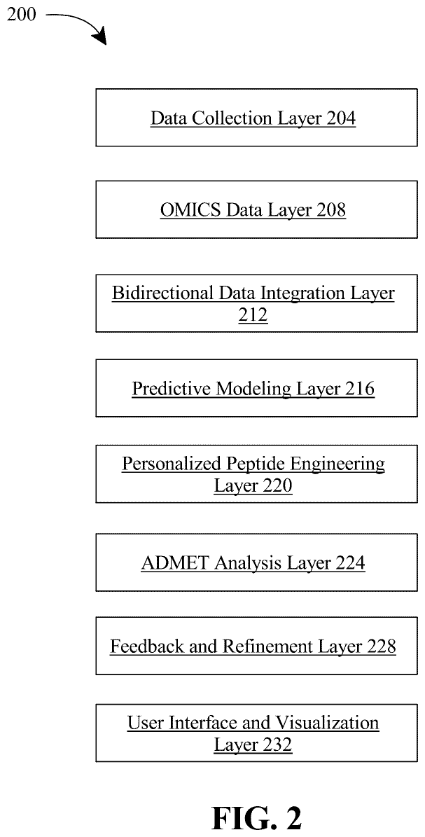

With continued reference to FIG. 1, in some embodiments, apparatus 100 may implement Organoid-To-Omics Bidirectional Data Interface (OTO-BDI) pipeline with an ADMET interface added for a complete therapeutic design workflow. In some embodiments, apparatus 100 may implement OTO-BDI with personalized peptide integration and ADMET Interface. In some embodiments, OTO-BDI (Organoid-To-Omics Bidirectional Data Interface) may be an advanced, integrated pipeline designed to facilitate bidirectional data flow between organoid models and OMICS datasets while incorporating personalized peptide engineering and ADMET (Absorption, Distribution, Metabolism, Excretion, and Toxicity) analysis for optimized therapeutic design. This enhanced pipeline may integrates multiple layer of data processing, prediction, and validation to ensure that the peptides engineered for specific molecular targets are safe, effective, and personalized. A system for OTO-BDI with ADMET integration is further described in detail with respect to FIG. 2.

With continued reference to FIG. 1, in some embodiments, primary objectives of apparatus 100 may include facilitating bidirectional data flow between organoid models and OMICS datasets to enable robust disease modeling, therapeutic design, and drug response prediction, engineering personalized peptides based on patient-specific OMICS data and validate their effectiveness and safety using organoid models, and/or integrating ADMET analysis to predict and ensure the pharmacokinetic properties and safety of peptides before clinical use.

With continued reference to FIG. 1, in some embodiments, exemplary use cases of apparatus 100 may include personalized peptide design for diseases such as cancer, autoimmune disorders, and viral infections (e.g., spike protein pathologies), prediction of drug efficacy and safety through organoid-based testing, ensuring personalized treatment plans, and/or peptide optimization for optimal therapeutic outcomes, with minimal toxicity or adverse reactions. Spike protein pathologies may include any pathologies as described in U.S. Provisional Patent Application No. 63/752,141 filed on Jan. 31, 2025 and entitled “SYSTEMS AND METHODS FOR POST-VACCINE SPIKE NEUTRALIZATION MULTIVALENT PEPTIDE DETECTION AND ENGINEERING” the entirety of which is incorporated herein by reference in its entirety.

With continued reference to FIG. 1, in some embodiments, exemplary use cases of apparatus 100 may include a case for spike protein pathology. In some embodiments, processor 104 may identify spike protein-induced molecular pathways and faulty immune responses from omics data 116, engineer peptides that specifically neutralize spike protein signaling, designed based on AI-driven peptide models, predict the pharmacokinetic properties of the peptides, including absorption, distribution, and potential toxicity, test peptides on spike protein-expressing organoids to evaluate efficacy and toxicity, and/or refine peptides using feedback from ADMET analysis and organoid response data.

Referring now to FIG. 2, a block diagram of an exemplary system 200 for OTO-BDI with ADMET integration is illustrated. System 200 may be consistent with apparatus 100. In some embodiments, core components of system 200 and/or apparatus 100 for OTO-BDI with ADMET integration may include organoid data collection layer 204 that collects live imaging, transcriptomics, proteomics, metabolomics, spike-related synthetic signatures, oncogenic potential scoring, and cellular behavior data from organoid cultures (organoid data 112). In some embodiments, organoid data collection may use confocal microscopy, multi-omics platforms (RNA-Seq, mass spectrometry), and organoid phenotyping technologies to collect organoid data 112.

With continued reference to FIG. 2, in some embodiments, core components of system 200 and/or apparatus 100 for OTO-BDI with ADMET integration may include a OMICS data layer 208. In some embodiments, OMICS data layer 208 may collect Genomic (exome, HLA), transcriptomic, proteomic, and metabolomic data (omics data 116). In some embodiments, OMICS data layer 208 may collect omics data 116 using RNA-Seq pipelines (e.g., STAR, DESeq2), proteomics platforms (e.g., MaxQuant), and metabolomics analysis tools.

With continued reference to FIG. 2, in some embodiments, core components of system 200 and/or apparatus 100 for OTO-BDI with ADMET integration may include a bidirectional data integration layer 212. In some embodiments, bidirectional data integration layer 212 may include a forward pathway (forward integration 152) for integration from organoid data 112 to omics data 116. In some embodiments, bidirectional data integration layer 212 may map organoid behavior (e.g., cellular response, protein expression) to molecular changes in omics data 116. In some embodiments, bidirectional data integration layer 212 may include a reverse pathway (reverse integration 156) for integration from omics data 116 to organoid data. In some embodiments, bidirectional data integration layer 212 may use OMICS-derived predictions to guide the design and testing of peptides or therapeutic agents in organoids. In some embodiments, bidirectional data integration layer 212 may include integration tools; for instance, data fusion frameworks (e.g., Nextflow, Galaxy), machine-learning algorithms (e.g., TensorFlow, PyTorch).

With continued reference to FIG. 2, in some embodiments, core components of system 200 and/or apparatus 100 for OTO-BDI with ADMET integration may include a predictive modeling layer 216. In some embodiments, predictive modeling layer 216 may include machine-learning models for disease pathway prediction, therapeutic target identification, and peptide optimization. In some embodiments, predictive modeling layer 216 may include Bayesian networks and advanced statistical models to integrate organoid data 112 and omics data 116. For the purposes of this disclosure, a “Bayesian network” is a probabilistic graphical model that represents a set of variables and their conditional dependencies through a directed acyclic graph. Bayesian networks can infer probabilistic relationships and quantify the uncertainty in predictions. In some embodiments, Bayesian network may be used to model the relationships between organoid data 112 (organoid-derived parameter 140) and omics data 116 (omics-derived parameter 144). In a non-limiting example, Bayesian network may predict how alterations in one dataset influence the other, facilitating identification of disease pathways 128.

With continued reference to FIG. 2, in some embodiments, core components of system 200 and/or apparatus 100 for OTO-BDI with ADMET integration may include a personalized peptide engineering layer 220. In some embodiments, personalized peptide engineering layer 220 may design a peptide by identifying faulty molecular pathways or targets (e.g., cytokines, spike proteins) from omics data 116, engineering peptides tailored to correct or neutralize these targets, and/or predicting peptide structure, binding affinity, and stability using advanced modeling tools. In some embodiments, personalized peptide engineering layer 220 may use engineering tools; for instance, AlphaFold and Rosetta for peptide structure prediction and Neo7Bioscience's PBIMA (Precision-Based Immunomolecular Augmentation) platform for peptide synthesis as described by U.S. application Ser. No. 19/445,844 and entitled “PRECISION-BASED IMMUNO-MOLECULAR AUGMENTATION (PBIMA) COMPUTERIZED SYSTEM, METHOD, AND THERAPEUTIC VACCINE filed on Jan. 12, 2026, the entirety of which is incorporated herein by reference in its entirety.

With continued reference to FIG. 2, in some embodiments, core components of system 200 and/or apparatus 100 for OTO-BDI with ADMET integration may include an ADMET analysis layer 224 may use in silico ADMET prediction tools (e.g., ADMETLab, SwissADME) to predict the absorption, distribution, metabolism, excretion, and toxicity of engineered peptides, evaluate the toxicity of peptides using organoid models to simulate potential adverse effects before clinical testing, and/or ensure optimal bioavailability, stability, and minimal toxicity in peptide candidates.

With continued reference to FIG. 2, in some embodiments, core components of system 200 and/or apparatus 100 for OTO-BDI with ADMET integration may include a feedback and refinement layer 228 that may incorporate real-time organoid feedback to refine peptide designs and OMICS predictions. In some embodiments, feedback and refinement layer 228 may configured to ADMET validation that may continually refine peptide design based on ADMET predictions and organoid model responses.

With continued reference to FIG. 2, in some embodiments, core components of system 200 and/or apparatus 100 for OTO-BDI with ADMET integration may include a user interface and visualization layer 232 that may generate interactive dashboards for real-time visualizations of organoid-omics integration, peptide predictions, and ADMET results. In some embodiments, user interface and visualization layer 232 may use tools such as TABLEAU® DASH®, or R SHINY for dynamic data exploration.

With continued reference to FIG. 2, in some embodiments, system 200 and/or apparatus 100 may include hardware and platforms including cloud-based infrastructure for scalable data storage and computation (e.g., AWS®, GOOGLE® cloud) and/or high-performance computing (HPC) clusters for complex peptide modeling and ADMET simulations.

With continued reference to FIG. 2, in some embodiments, system 200 and/or apparatus 100 may include software tools for data integration: for instance, Nextflow, Galaxy for workflow orchestration. In some embodiments, system 200 and/or apparatus 100 may include software tools for machine-learning: for instance, TensorFlow, PyTorch for predictive models and peptide optimization. In some embodiments, system 200 and/or apparatus 100 may include software tools for peptide modeling: for instance, AlphaFold, Rosetta for accurate structure prediction. In some embodiments, system 200 and/or apparatus 100 may include software tools for ADMET analysis: for instance, ADMETLab, SwissADME for in silico pharmacokinetics and toxicity analysis. In some embodiments, system 200 and/or apparatus 100 may include software tools for visualization: for instance, Tableau, Dash, R Shiny for real-time user interfaces and data exploration. In some embodiments, system 200 and/or apparatus 100 may include software tools for pipeline automation: for instance, Snakemake, Airflow for continuous integration and feedback cycles. In some embodiments, system 200 and/or apparatus 100 may be configured for real-time feedback loops for seamless integration of omics data 116, organoid data 112, peptide datum 132, and ADMET datum 148 for adaptive model optimization.

With continued reference to FIG. 2, in some embodiments, system 200 and/or apparatus 100 may be configured for scalability: for instance, modular pipelines to focus on specific diseases (e.g., cancer, autoimmune disorders, viral infections). In some embodiments, system 200 and/or apparatus 100 may be configured for collaboration to enable multi-institutional access through secure cloud-based platforms for data sharing and joint validation. In some embodiments, system 200 and/or apparatus 100 may be configured for clinical readiness to ensure peptides undergo comprehensive ADMET validation and organoid-based testing before moving into clinical trials.

With continued reference to FIG. 2, in some embodiments, OTO-BDI pipeline with personalized peptide engineering and ADMET analysis may provide a robust, dynamic framework for designing safe and effective therapies based on patient-specific molecular data. By combining advanced organoid modeling, OMICS data integration, AI-driven peptide design, and in silico ADMET prediction, this pipeline may be poised.

Referring now to FIG. 3, a configuration of an exemplary user interface 176 on a user device 180. In some embodiments, user interface 176 may display integrated data 124, peptide datum 132 and ADMET datum 148 on a user device 180. In some embodiments, user may manipulate user interface 176 to input user feedback 136.

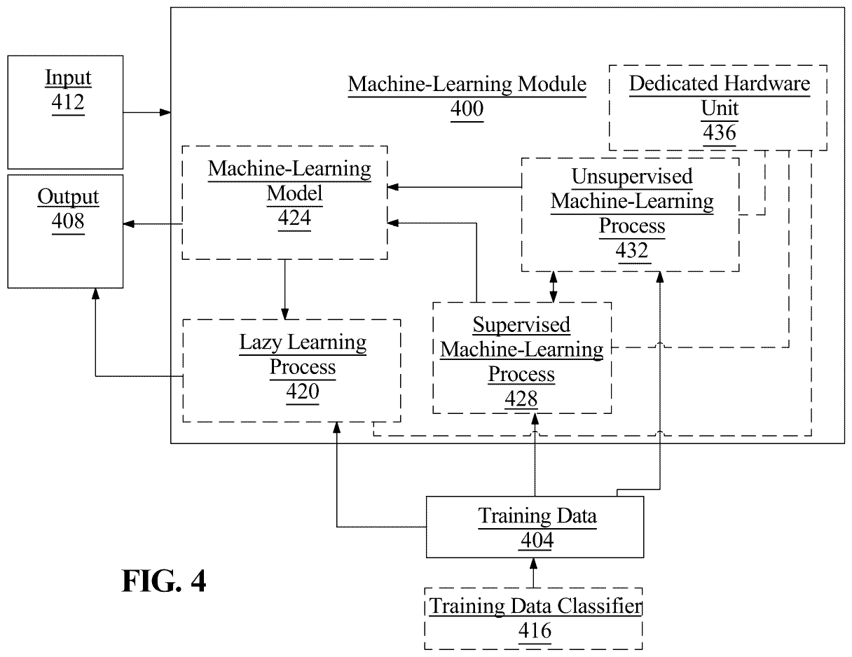

Referring now to FIG. 4, an exemplary embodiment of a machine-learning module 400 that may perform one or more machine-learning processes as described in this disclosure is illustrated. Machine-learning module may perform determinations, classification, and/or analysis steps, methods, processes, or the like as described in this disclosure using machine-learning processes. A “machine-learning process,” as used in this disclosure, is a process that automatedly uses training data 404 to generate an algorithm instantiated in hardware or software logic, data structures, and/or functions that will be performed by a computing device/module to produce outputs 408 given data provided as inputs 412; this is in contrast to a non-machine-learning software program where the commands to be executed are determined in advance by a user and written in a programming language.

Still referring to FIG. 4, “training data,” as used herein, is data containing correlations that a machine-learning process may use to model relationships between two or more categories of data elements. For instance, and without limitation, training data 404 may include a plurality of data entries, also known as “training examples,” each entry representing a set of data elements that were recorded, received, and/or generated together; data elements may be correlated by shared existence in a given data entry, by proximity in a given data entry, or the like. Multiple data entries in training data 404 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 404 according to various correlations; correlations may indicate causative and/or predictive links between categories of data elements, which may be modeled as relationships such as mathematical relationships by machine-learning processes as described in further detail below. Training data 404 may be formatted and/or organized by categories of data elements, for instance by associating data elements with one or more descriptors corresponding to categories of data elements. As a non-limiting example, training data 404 may include data entered in standardized forms by persons or processes, such that entry of a given data element in a given field in a form may be mapped to one or more descriptors of categories. Elements in training data 404 may be linked to descriptors of categories by tags, tokens, or other data elements; for instance, and without limitation, training data 404 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 4, training data 404 may include one or more elements that are not categorized; that is, training data 404 may not be formatted or contain descriptors for some elements of data. Machine-learning algorithms and/or other processes may sort training data 404 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 404 to be made applicable for two or more distinct machine-learning algorithms as described in further detail below. Training data 404 used by machine-learning module 400 may correlate any input data as described in this disclosure to any output data as described in this disclosure. As a non-limiting illustrative example, input data may include organoid data, omics data, integrated data, disease pathway, peptide datum, user feedback, organoid-derived parameter, omics-derived parameter, toxicity, and the like. As a non-limiting illustrative example, output data may include integrated data, disease pathway, peptide datum, user feedback, organoid-derived parameter, omics-derived parameter, toxicity, ADMET datum, and the like.

Further referring to FIG. 4, training data may be filtered, sorted, and/or selected using one or more supervised and/or unsupervised machine-learning processes and/or models as described in further detail below; such models may include without limitation a training data classifier 416. Training data classifier 416 may include a “classifier,” which as used in this disclosure is a machine-learning model as defined below, such as a data structure representing and/or using a mathematical model, neural net, or program generated by a machine-learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. A distance metric may include any norm, such as, without limitation, a Pythagorean norm. Machine-learning module 400 may generate a classifier using a classification algorithm, defined as a processes whereby a computing device and/or any module and/or component operating thereon derives a classifier from training data 404. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 416 may classify elements of training data to cohort that is related to a user demographic, subject or patient demographic, and the like.

Still referring to FIG. 4, computing device may be configured to generate a classifier using a Naïve Bayes classification algorithm. Naïve Bayes classification algorithm generates classifiers by assigning class labels to problem instances, represented as vectors of element values. Class labels are drawn from a finite set. Naïve Bayes classification algorithm may include generating a family of algorithms that assume that the value of a particular element is independent of the value of any other element, given a class variable. Naïve Bayes classification algorithm may be based on Bayes Theorem expressed as P(A/B)=P(B/A) P(A)=P(B), where P(A/B) is the probability of hypothesis A given data B also known as posterior probability; P(B/A) is the probability of data B given that the hypothesis A was true; P(A) is the probability of hypothesis A being true regardless of data also known as prior probability of A; and P(B) is the probability of the data regardless of the hypothesis. A naïve Bayes algorithm may be generated by first transforming training data into a frequency table. Computing device may then calculate a likelihood table by calculating probabilities of different data entries and classification labels. Computing device may utilize a naïve Bayes equation to calculate a posterior probability for each class. A class containing the highest posterior probability is the outcome of prediction. Naïve Bayes classification algorithm may include a gaussian model that follows a normal distribution. Naïve Bayes classification algorithm may include a multinomial model that is used for discrete counts. Naïve Bayes classification algorithm may include a Bernoulli model that may be utilized when vectors are binary.

With continued reference to FIG. 4, computing device may be configured to generate a classifier using a K-nearest neighbors (KNN) algorithm. A “K-nearest neighbors algorithm” as used in this disclosure, includes a classification method that utilizes feature similarity to analyze how closely out-of-sample-features resemble training data to classify input data to one or more clusters and/or categories of features as represented in training data; this may be performed by representing both training data and input data in vector forms, and using one or more measures of vector similarity to identify classifications within training data, and to determine a classification of input data. K-nearest neighbors algorithm may include specifying a K-value, or a number directing the classifier to select the k most similar entries training data to a given sample, determining the most common classifier of the entries in the database, and classifying the known sample; this may be performed recursively and/or iteratively to generate a classifier that may be used to classify input data as further samples. For instance, an initial set of samples may be performed to cover an initial heuristic and/or “first guess” at an output and/or relationship, which may be seeded, without limitation, using expert input received according to any process as described herein. As a non-limiting example, an initial heuristic may include a ranking of associations between inputs and elements of training data. Heuristic may include selecting some number of highest-ranking associations and/or training data elements.

With continued reference to FIG. 4, generating k-nearest neighbors algorithm may generate a first vector output containing a data entry cluster, generating a second vector output containing an input data, and calculate the distance between the first vector output and the second vector output using any suitable norm such as cosine similarity, Euclidean distance measurement, or the like. Each vector output may be represented, without limitation, as an n-tuple of values, where n is at least two values. Each value of n-tuple of values may represent a measurement or other quantitative value associated with a given category of data, or attribute, examples of which are provided in further detail below; a vector may be represented, without limitation, in n-dimensional space using an axis per category of value represented in n-tuple of values, such that a vector has a geometric direction characterizing the relative quantities of attributes in the n-tuple as compared to each other. Two vectors may be considered equivalent where their directions, and/or the relative quantities of values within each vector as compared to each other, are the same; thus, as a non-limiting example, a vector represented as [5, 10, 15] may be treated as equivalent, for purposes of this disclosure, as a vector represented as [1, 2, 3]. Vectors may be more similar where their directions are more similar, and more different where their directions are more divergent; however, vector similarity may alternatively or additionally be determined using averages of similarities between like attributes, or any other measure of similarity suitable for any n-tuple of values, or aggregation of numerical similarity measures for the purposes of loss functions as described in further detail below. Any vectors as described herein may be scaled, such that each vector represents each attribute along an equivalent scale of values. Each vector may be “normalized,” or divided by a “length” attribute, such as a length attribute I as derived using a Pythagorean norm:

$$l = \sqrt{{\sum }_{i = 0}^{n} {a}_{i}^{2} ,}$$

where aᵢ is attribute number i of the vector. Scaling and/or normalization may function to make vector comparison independent of absolute quantities of attributes, while preserving any dependency on similarity of attributes; this may, for instance, be advantageous where cases represented in training data are represented by different quantities of samples, which may result in proportionally equivalent vectors with divergent values.

With further reference to FIG. 4, training examples for use as training data may be selected from a population of potential examples according to cohorts relevant to an analytical problem to be solved, a classification task, or the like. Alternatively or additionally, training data may be selected to span a set of likely circumstances or inputs for a machine-learning model and/or process to encounter when deployed. For instance, and without limitation, for each category of input data to a machine-learning process or model that may exist in a range of values in a population of phenomena such as images, user data, process data, physical data, or the like, a computing device, processor, and/or machine-learning model may select training examples representing each possible value on such a range and/or a representative sample of values on such a range. Selection of a representative sample may include selection of training examples in proportions matching a statistically determined and/or predicted distribution of such values according to relative frequency, such that, for instance, values encountered more frequently in a population of data so analyzed are represented by more training examples than values that are encountered less frequently. Alternatively or additionally, a set of training examples may be compared to a collection of representative values in a database and/or presented to a user, so that a process can detect, automatically or by user feedback 136, one or more values that are not included in the set of training examples. Computing device, processor, and/or module may automatically generate a missing training example; this may be done by receiving and/or retrieving a missing input and/or output value and correlating the missing input and/or output value with a corresponding output and/or input value collocated in a data record with the retrieved value, provided by a user and/or other device, or the like.

Continuing to refer to FIG. 4, computer, processor, and/or module may be configured to preprocess training data. “Preprocessing” training data, as used in this disclosure, is transforming training data from raw form to a format that can be used for training a machine-learning model. Preprocessing may include sanitizing, feature selection, feature scaling, data augmentation and the like.

Still referring to FIG. 4, computer, processor, and/or module may be configured to sanitize training data. “Sanitizing” training data, as used in this disclosure, is a process whereby training examples are removed that interfere with convergence of a machine-learning model and/or process to a useful result. For instance, and without limitation, a training example may include an input and/or output value that is an outlier from typically encountered values, such that a machine-learning algorithm using the training example will be adapted to an unlikely amount as an input and/or output; a value that is more than a threshold number of standard deviations away from an average, mean, or expected value, for instance, may be eliminated. Alternatively or additionally, one or more training examples may be identified as having poor quality data, where “poor quality” is defined as having a signal to noise ratio below a threshold value. Sanitizing may include steps such as removing duplicative or otherwise redundant data, interpolating missing data, correcting data errors, standardizing data, identifying outliers, and the like. In a nonlimiting example, sanitization may include utilizing algorithms for identifying duplicate entries or spell-check algorithms.

As a non-limiting example, and with further reference to FIG. 4, images used to train an image classifier or other machine-learning model and/or process that takes images as inputs or generates images as outputs may be rejected if image quality is below a threshold value. For instance, and without limitation, computing device, processor, and/or module may perform blur detection, and eliminate one or more Blur detection may be performed, as a non-limiting example, by taking Fourier transform, or an approximation such as a Fast Fourier Transform (FFT) of the image and analyzing a distribution of low and high frequencies in the resulting frequency-domain depiction of the image; numbers of high-frequency values below a threshold level may indicate blurriness. As a further non-limiting example, detection of blurriness may be performed by convolving an image, a channel of an image, or the like with a Laplacian kernel; this may generate a numerical score reflecting a number of rapid changes in intensity shown in the image, such that a high score indicates clarity and a low score indicates blurriness. Blurriness detection may be performed using a gradient-based operator, which measures operators based on the gradient or first derivative of an image, based on the hypothesis that rapid changes indicate sharp edges in the image, and thus are indicative of a lower degree of blurriness. Blur detection may be performed using Wavelet-based operator, which takes advantage of the capability of coefficients of the discrete wavelet transform to describe the frequency and spatial content of images. Blur detection may be performed using statistics-based operators take advantage of several image statistics as texture descriptors in order to compute a focus level. Blur detection may be performed by using discrete cosine transform (DCT) coefficients in order to compute a focus level of an image from its frequency content.

Continuing to refer to FIG. 4, computing device, processor, and/or module may be configured to precondition one or more training examples. For instance, and without limitation, where a machine-learning model and/or process has one or more inputs and/or outputs requiring, transmitting, or receiving a certain number of bits, samples, or other units of data, one or more training examples' elements to be used as or compared to inputs and/or outputs may be modified to have such a number of units of data. For instance, a computing device, processor, and/or module may convert a smaller number of units, such as in a low pixel count image, into a desired number of units, for instance by upsampling and interpolating. As a non-limiting example, a low pixel count image may have 100 pixels, however a desired number of pixels may be 128. Processor may interpolate the low pixel count image to convert the 100 pixels into 128 pixels. It should also be noted that one of ordinary skill in the art, upon reading this disclosure, would know the various methods to interpolate a smaller number of data units such as samples, pixels, bits, or the like to a desired number of such units. In some instances, a set of interpolation rules may be trained by sets of highly detailed inputs and/or outputs and corresponding inputs and/or outputs downsampled to smaller numbers of units, and a neural network or other machine-learning model that is trained to predict interpolated pixel values using the training data. As a non-limiting example, a sample input and/or output, such as a sample picture, with sample-expanded data units (e.g., pixels added between the original pixels) may be input to a neural network or machine-learning model and output a pseudo replica sample-picture with dummy values assigned to pixels between the original pixels based on a set of interpolation rules. As a non-limiting example, in the context of an image classifier, a machine-learning model may have a set of interpolation rules trained by sets of highly detailed images and images that have been downsampled to smaller numbers of pixels, and a neural network or other machine-learning model that is trained using those examples to predict interpolated pixel values in a facial picture context. As a result, an input with sample-expanded data units (the ones added between the original data units, with dummy values) may be run through a trained neural network and/or model, which may fill in values to replace the dummy values. Alternatively or additionally, processor, computing device, and/or module may utilize sample expander methods, a low-pass filter, or both. As used in this disclosure, a “low-pass filter” is a filter that passes signals with a frequency lower than a selected cutoff frequency and attenuates signals with frequencies higher than the cutoff frequency. The exact frequency response of the filter depends on the filter design. Computing device, processor, and/or module may use averaging, such as luma or chroma averaging in images, to fill in data units in between original data units.

In some embodiments, and with continued reference to FIG. 4, computing device, processor, and/or module may down-sample elements of a training example to a desired lower number of data elements. As a non-limiting example, a high pixel count image may have 256 pixels, however a desired number of pixels may be 128. Processor may down-sample the high pixel count image to convert the 256 pixels into 128 pixels. In some embodiments, processor may be configured to perform downsampling on data. Downsampling, also known as decimation, may include removing every Nth entry in a sequence of samples, all but every Nth entry, or the like, which is a process known as “compression,” and may be performed, for instance by an N-sample compressor implemented using hardware or software. Anti-aliasing and/or anti-imaging filters, and/or low-pass filters, may be used to clean up side-effects of compression.

Further referring to FIG. 4, feature selection includes narrowing and/or filtering training data to exclude features and/or elements, or training data including such elements, that are not relevant to a purpose for which a trained machine-learning model and/or algorithm is being trained, and/or collection of features and/or elements, or training data including such elements, on the basis of relevance or utility for an intended task or purpose for a trained machine-learning model and/or algorithm is being trained. Feature selection may be implemented, without limitation, using any process described in this disclosure, including without limitation using training data classifiers, exclusion of outliers, or the like.

With continued reference to FIG. 4, feature scaling may include, without limitation, normalization of data entries, which may be accomplished by dividing numerical fields by norms thereof, for instance as performed for vector normalization. Feature scaling may include absolute maximum scaling, wherein each quantitative datum is divided by the maximum absolute value of all quantitative data of a set or subset of quantitative data. Feature scaling may include min-max scaling, in which each value X has a minimum value Xₘᵢₙ in a set or subset of values subtracted therefrom, with the result divided by the range of the values, give maximum value in the set or subset Xₘₐₓ:

$${X}_{new} = \frac{X - {X}_{min}}{{X}_{max} - {X}_{min}} .$$

Feature scaling may include mean normalization, which involves use of a mean value of a set and/or subset of values, Xₘₑₐₙ with maximum and minimum values:

$${X}_{new} = \frac{X - {X}_{mean}}{{X}_{max} - {X}_{min}} .$$

Feature scaling may include standardization, where a difference between X and Xₘₑₐₙ is divided by a standard deviation σ of a set or subset of values:

$${X}_{new} = \frac{X - {X}_{mean}}{σ} .$$

Scaling may be performed using a median value of a set or subset X_{median} and/or interquartile range (IQR), which represents the difference between the 25^{th} percentile value and the 50^{th} percentile value (or closest values thereto by a rounding protocol), such as:

$${X}_{new} = \frac{X - {X}_{median}}{IQR} .$$

Persons skilled in the art, upon reviewing the entirety of this disclosure, will be aware of various alternative or additional approaches that may be used for feature scaling.

Further referring to FIG. 4, computing device, processor, and/or module may be configured to perform one or more processes of data augmentation. “Data augmentation” as used in this disclosure is addition of data to a training set using elements and/or entries already in the dataset. Data augmentation may be accomplished, without limitation, using interpolation, generation of modified copies of existing entries and/or examples, and/or one or more generative AI processes, for instance using deep neural networks and/or generative adversarial networks; generative processes may be referred to alternatively in this context as “data synthesis” and as creating “synthetic data.” Augmentation may include performing one or more transformations on data, such as geometric, color space, affine, brightness, cropping, and/or contrast transformations of images.

Still referring to FIG. 4, machine-learning module 400 may be configured to perform a lazy-learning process 420 and/or protocol, which may alternatively be referred to as a “lazy loading” or “call-when-needed” process and/or protocol, may be a process whereby machine-learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 404. Heuristic may include selecting some number of highest-ranking associations and/or training data 404 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 4, machine-learning processes as described in this disclosure may be used to generate machine-learning models 424. A “machine-learning model,” as used in this disclosure, is a data structure representing and/or instantiating a mathematical and/or algorithmic representation of a relationship between inputs and outputs, as generated using any machine-learning process including without limitation any process as described above, and stored in memory; an input is submitted to a machine-learning model 424 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 424 may be generated by creating an artificial neural network, such as a convolutional neural network comprising an input layer of nodes, one or more intermediate layers, and an output layer of nodes. Connections between nodes may be created via the process of “training” the network, in which elements from a training data 404 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 4, machine-learning algorithms may include at least a supervised machine-learning process 428. At least a supervised machine-learning process 428, as defined herein, include algorithms that receive a training set relating a number of inputs to a number of outputs, and seek to generate one or more data structures representing and/or instantiating one or more mathematical relations relating inputs to outputs, where each of the one or more mathematical relations is optimal according to some criterion specified to the algorithm using some scoring function. For instance, a supervised learning algorithm may include organoid data, omics data, integrated data, disease pathway, peptide datum, user feedback, organoid-derived parameter, omics-derived parameter, toxicity, and the like as described above as inputs, integrated data, disease pathway, peptide datum, user feedback, organoid-derived parameter, omics-derived parameter, toxicity, ADMET datum, and the like as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 404. Persons skilled in the art, upon reviewing the entirety of this disclosure, will be aware of various possible variations of at least a supervised machine-learning process 428 that may be used to determine relation between inputs and outputs. Supervised machine-learning processes may include classification algorithms as defined above.

With further reference to FIG. 4, training a supervised machine-learning process may include, without limitation, iteratively updating coefficients, biases, weights based on an error function, expected loss, and/or risk function. For instance, an output generated by a supervised machine-learning model using an input example in a training example may be compared to an output example from the training example; an error function may be generated based on the comparison, which may include any error function suitable for use with any machine-learning algorithm described in this disclosure, including a square of a difference between one or more sets of compared values or the like. Such an error function may be used in turn to update one or more weights, biases, coefficients, or other parameters of a machine-learning model through any suitable process including without limitation gradient descent processes, least-squares processes, and/or other processes described in this disclosure. This may be done iteratively and/or recursively to gradually tune such weights, biases, coefficients, or other parameters. Updating may be performed, in neural networks, using one or more back-propagation algorithms. Iterative and/or recursive updates to weights, biases, coefficients, or other parameters as described above may be performed until currently available training data is exhausted and/or until a convergence test is passed, where a “convergence test” is a test for a condition selected as indicating that a model and/or weights, biases, coefficients, or other parameters thereof has reached a degree of accuracy. A convergence test may, for instance, compare a difference between two or more successive errors or error function values, where differences below a threshold amount may be taken to indicate convergence. Alternatively or additionally, one or more errors and/or error function values evaluated in training iterations may be compared to a threshold.

Still referring to FIG. 4, a computing device, processor, and/or module may be configured to perform method, method step, sequence of method steps and/or algorithm described in reference to this figure, in any order and with any degree of repetition. For instance, a computing device, processor, and/or module may be configured to perform a single step, sequence and/or algorithm repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. A computing device, processor, and/or module may perform any step, sequence of steps, or algorithm in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

Further referring to FIG. 4, machine-learning processes may include at least an unsupervised machine-learning processes 432. An unsupervised machine-learning process, as used herein, is a process that derives inferences in datasets without regard to labels; as a result, an unsupervised machine-learning process may be free to discover any structure, relationship, and/or correlation provided in the data. Unsupervised processes 432 may not require a response variable; unsupervised processes 432 may be used to find interesting patterns and/or inferences between variables, to determine a degree of correlation between two or more variables, or the like.

Still referring to FIG. 4, machine-learning module 400 may be designed and configured to create a machine-learning model 424 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 4, machine-learning algorithms may include, without limitation, linear discriminant analysis. Machine-learning algorithm may include quadratic discriminant analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include various forms of latent space regularization such as variational regularization. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized trees, AdaBoost, gradient tree boosting, and/or voting classifier methods. Machine-learning algorithms may include neural net algorithms, including convolutional neural net processes.

Still referring to FIG. 4, a machine-learning model and/or process may be deployed or instantiated by incorporation into a program, apparatus, system and/or module. For instance, and without limitation, a machine-learning model, neural network, and/or some or all parameters thereof may be stored and/or deployed in any memory or circuitry. Parameters such as coefficients, weights, and/or biases may be stored as circuit-based constants, such as arrays of wires and/or binary inputs and/or outputs set at logic “1” and “0” voltage levels in a logic circuit to represent a number according to any suitable encoding system including twos complement or the like or may be stored in any volatile and/or non-volatile memory. Similarly, mathematical operations and input and/or output of data to or from models, neural network layers, or the like may be instantiated in hardware circuitry and/or in the form of instructions in firmware, machine-code such as binary operation code instructions, assembly language, or any higher-order programming language. Any technology for hardware and/or software instantiation of memory, instructions, data structures, and/or algorithms may be used to instantiate a machine-learning process and/or model, including without limitation any combination of production and/or configuration of non-reconfigurable hardware elements, circuits, and/or modules such as without limitation ASICs, production and/or configuration of reconfigurable hardware elements, circuits, and/or modules such as without limitation FPGAs, production and/or of non-reconfigurable and/or configuration non-rewritable memory elements, circuits, and/or modules such as without limitation non-rewritable ROM, production and/or configuration of reconfigurable and/or rewritable memory elements, circuits, and/or modules such as without limitation rewritable ROM or other memory technology described in this disclosure, and/or production and/or configuration of any computing device and/or component thereof as described in this disclosure. Such deployed and/or instantiated machine-learning model and/or algorithm may receive inputs from any other process, module, and/or component described in this disclosure, and produce outputs to any other process, module, and/or component described in this disclosure.

Continuing to refer to FIG. 4, any process of training, retraining, deployment, and/or instantiation of any machine-learning model and/or algorithm may be performed and/or repeated after an initial deployment and/or instantiation to correct, refine, and/or improve the machine-learning model and/or algorithm. Such retraining, deployment, and/or instantiation may be performed as a periodic or regular process, such as retraining, deployment, and/or instantiation at regular elapsed time periods, after some measure of volume such as a number of bytes or other measures of data processed, a number of uses or performances of processes described in this disclosure, or the like, and/or according to a software, firmware, or other update schedule. Alternatively or additionally, retraining, deployment, and/or instantiation may be event-based, and may be triggered, without limitation, by user feedback 136 indicating sub-optimal or otherwise problematic performance and/or by automated field testing and/or auditing processes, which may compare outputs of machine-learning models and/or algorithms, and/or errors and/or error functions thereof, to any thresholds, convergence tests, or the like, and/or may compare outputs of processes described herein to similar thresholds, convergence tests or the like. Event-based retraining, deployment, and/or instantiation may alternatively or additionally be triggered by receipt and/or generation of one or more new training examples; a number of new training examples may be compared to a preconfigured threshold, where exceeding the preconfigured threshold may trigger retraining, deployment, and/or instantiation.

Still referring to FIG. 4, retraining and/or additional training may be performed using any process for training described above, using any currently or previously deployed version of a machine-learning model and/or algorithm as a starting point. Training data for retraining may be collected, preconditioned, sorted, classified, sanitized or otherwise processed according to any process described in this disclosure. Training data may include, without limitation, training examples including inputs and correlated outputs used, received, and/or generated from any version of any system, module, machine-learning model or algorithm, apparatus, and/or method described in this disclosure; such examples may be modified and/or labeled according to user feedback or other processes to indicate desired results, and/or may have actual or measured results from a process being modeled and/or predicted by system, module, machine-learning model or algorithm, apparatus, and/or method as “desired” results to be compared to outputs for training processes as described above.

Redeployment may be performed using any reconfiguring and/or rewriting of reconfigurable and/or rewritable circuit and/or memory elements; alternatively, redeployment may be performed by production of new hardware and/or software components, circuits, instructions, or the like, which may be added to and/or may replace existing hardware and/or software components, circuits, instructions, or the like.

Further referring to FIG. 4, one or more processes or algorithms described above may be performed by at least a dedicated hardware unit 436. A “dedicated hardware unit,” for the purposes of this figure, is a hardware component, circuit, or the like, aside from a principal control circuit and/or processor performing method steps as described in this disclosure, that is specifically designated or selected to perform one or more specific tasks and/or processes described in reference to this figure, such as without limitation preconditioning and/or sanitization of training data and/or training a machine-learning algorithm and/or model. A dedicated hardware unit 436 may include, without limitation, a hardware unit that can perform iterative or massed calculations, such as matrix-based calculations to update or tune parameters, weights, coefficients, and/or biases of machine-learning models and/or neural networks, efficiently using pipelining, parallel processing, or the like; such a hardware unit may be optimized for such processes by, for instance, including dedicated circuitry for matrix and/or signal processing operations that includes, e.g., multiple arithmetic and/or logical circuit units such as multipliers and/or adders that can act simultaneously and/or in parallel or the like. Such dedicated hardware units 436 may include, without limitation, graphical processing units (GPUs), dedicated signal processing modules, FPGA or other reconfigurable hardware that has been configured to instantiate parallel processing units for one or more specific tasks, or the like, A computing device, processor, apparatus, or module may be configured to instruct one or more dedicated hardware units 436 to perform one or more operations described herein, such as evaluation of model and/or algorithm outputs, one-time or iterative updates to parameters, coefficients, weights, and/or biases, and/or any other operations such as vector and/or matrix operations as described in this disclosure.

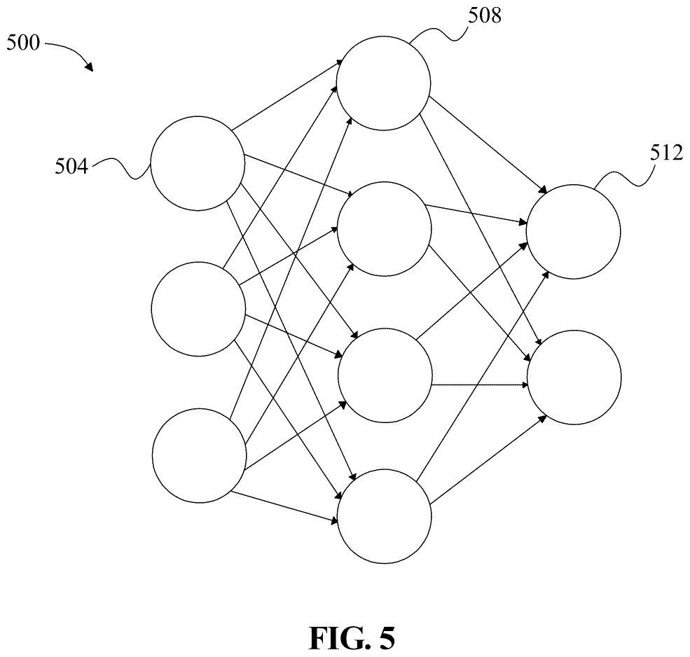

Referring now to FIG. 5, an exemplary embodiment of neural network 500 is illustrated. A neural network 500 also known as an artificial neural network, is a network of “nodes,” or data structures having one or more inputs, one or more outputs, and a function determining outputs based on inputs. Such nodes may be organized in a network, such as without limitation a convolutional neural network, including an input layer of nodes 504, one or more intermediate layers 508, and an output layer of nodes 512. Connections between nodes may be created via the process of “training” the network, in which elements from a training dataset are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning. Connections may run solely from input nodes toward output nodes in a “feed-forward” network, or may feed outputs of one layer back to inputs of the same or a different layer in a “recurrent network.” As a further non-limiting example, a neural network may include a convolutional neural network comprising an input layer of nodes, one or more intermediate layers, and an output layer of nodes. A “convolutional neural network,” as used in this disclosure, is a neural network in which at least one hidden layer is a convolutional layer that convolves inputs to that layer with a subset of inputs known as a “kernel,” along with one or more additional layers such as pooling layers, fully connected layers, and the like.

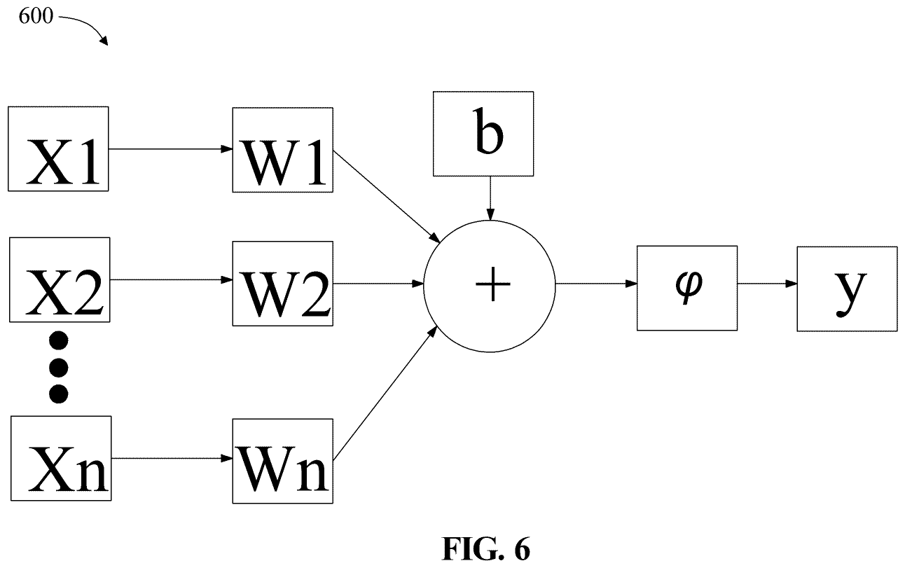

Referring now to FIG. 6, an exemplary embodiment of a node 600 of a neural network is illustrated. A node may include, without limitation a plurality of inputs xi that may receive numerical values from inputs to a neural network containing the node and/or from other nodes. Node may perform one or more activation functions to produce its output given one or more inputs, such as without limitation computing a binary step function comparing an input to a threshold value and outputting either a logic 1 or logic 0 output or something equivalent, a linear activation function whereby an output is directly proportional to the input, and/or a non-linear activation function, wherein the output is not proportional to the input. Non-linear activation functions may include, without limitation, a sigmoid function of the form

$$f ( x ) = \frac{1}{1 - {e}^{- x}}$$

given input x, a tanh (hyperbolic tangent) function, of the form

$$\frac{{e}^{x} - {e}^{- x}}{{e}^{x} + {e}^{- x}} ,$$

a tanh derivative function such as f(x)=tanh²(x), a rectified linear unit function such as f(x)=max(0, x), a “leaky” and/or “parametric” rectified linear unit function such as f(x)=max(ax, x) for some a, an exponential linear units function such as

$$f ( x ) = \{ \begin{matrix}x for x \geq 0 \\ α ( {e}^{x} - 1 ) for x < 0\end{matrix}$$

for some value of α (this function may be replaced and/or weighted by its own derivative in some embodiments), a softmax function such as

$$f ( {x}_{i} ) = \frac{{e}^{x}}{{\sum }_{i} {x}_{i}}$$

where the inputs to an instant layer are xi, a swish function such as f(x)=x*sigmoid(x), a Gaussian error linear unit function such as f(x)=a(1+tanh(\sqrt{2/π}(x+bx^{r}))) for some values of a, b, and r, and/or a scaled exponential linear unit function such as

$$f ( x ) = λ \{ \begin{matrix}α ( {e}^{x} - 1 ) for x < 0 \\ x for x \geq 0\end{matrix} .$$

Fundamentally, there is no limit to the nature of functions of inputs xi that may be used as activation functions. As a non-limiting and illustrative example, node may perform a weighted sum of inputs using weights wᵢ that are multiplied by respective inputs xᵢ. Additionally or alternatively, a bias b may be added to the weighted sum of the inputs such that an offset is added to each unit in the neural network layer that is independent of the input to the layer. The weighted sum may then be input into a function φ, which may generate one or more outputs y. Weight wᵢ applied to an input xᵢ may indicate whether the input is “excitatory,” indicating that it has strong influence on the one or more outputs y, for instance by the corresponding weight having a large numerical value, and/or a “inhibitory,” indicating it has a weak effect influence on the one more inputs y, for instance by the corresponding weight having a small numerical value. The values of weights wᵢ may be determined by training a neural network using training data, which may be performed using any suitable process as described above.

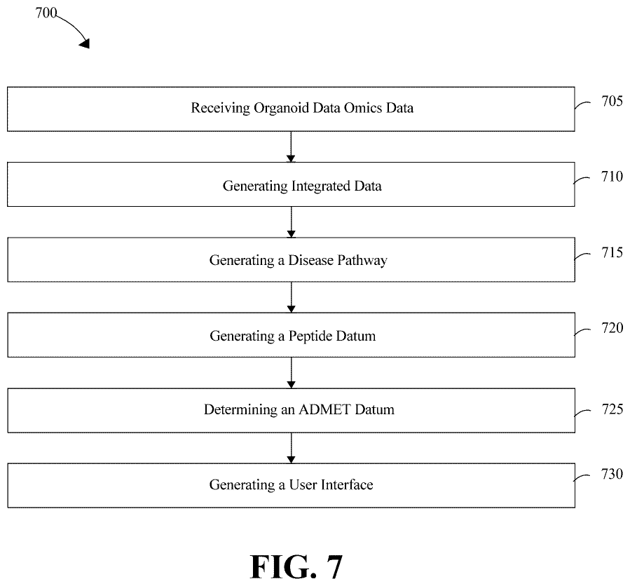

Referring now to FIG. 7, a flow diagram of an exemplary method 700 for bidirectional data integration is illustrated. Method 700 contains a step 705 of receiving, using at least a processor, organoid data and omics data. In some embodiments, receiving the organoid data and the omics data may include normalizing the organoid data and the omics data to remove noise, batch effects and biases. In some embodiments, receiving the organoid data and the omics data may include extracting the at least an organoid-derived parameter and the at least an omics-derived parameter as a function of the organoid data and the omics data. These may be implemented as referenced to FIGS. 1-6.

With continued reference to FIG. 7, method 700 contains a step 710 of generating, using at least a processor, integrated data by integrating organoid data and omics data bidirectionally, wherein integrating the organoid data and the omics data bidirectionally comprises includes forward integration to correlate at least an organoid-derived parameter of the organoid data to molecular changes of the omics data and reverse integration to correlate at least an omics-derived parameter of the omics data to therapeutic agents of the organoid data. These may be implemented as referenced to FIGS. 1-6.

With continued reference to FIG. 7, method 700 contains a step 715 of generating, using at least a processor, a disease pathway as a function of integrated data. This may be implemented as referenced to FIGS. 1-6.

With continued reference to FIG. 7, method 700 contains a step 720 of generating, using at least a processor, a peptide datum using a machine-learning model as a function of integrated data and a disease pathway. In some embodiments, generating the peptide datum may include generating the peptide datum as a function of affinity, stability, and therapeutic efficacy. In some embodiments, generating the peptide datum may include generating peptide training data, wherein the peptide training data may include exemplary integrated data and exemplary disease pathways correlated to exemplary peptide data, training a machine-learning model using the peptide training data and generating the peptide datum using the trained peptide machine-learning model. These may be implemented as referenced to FIGS. 1-6.

With continued reference to FIG. 7, method 700 contains a step 725 of determining, using at least a processor, an absorption, distribution, metabolism, excretion, and toxicity (ADMET) datum as a function of the peptide datum. In some embodiments, determining the ADMET datum may include receiving user feedback for the displayed peptide datum and the ADMET datum and updating the peptide datum and the ADMET datum as a function of the user feedback. In some embodiments, determining the ADMET datum may include updating the peptide datum as a function of the ADMET datum. In some embodiments, determining the ADMET datum may include conducting in silico ADMET analysis to simulate pharmacokinetics and toxicity profiles of the peptide datum. In some embodiments, determining the ADMET datum may include assessing toxicity of the peptide datum using organoid-based toxicity assays. In some embodiments, determining the ADMET datum may include optimizing the peptide datum as a function of the ADMET datum and the toxicity of the peptide datum. These may be implemented as referenced to FIGS. 1-6.

With continued reference to FIG. 7, method 700 contains a step 730 of generating, using at least a processor, a user interface displaying the integrated data, the peptide datum and the ADMET datum on a user device. This may be implemented as referenced to FIGS. 1-6.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

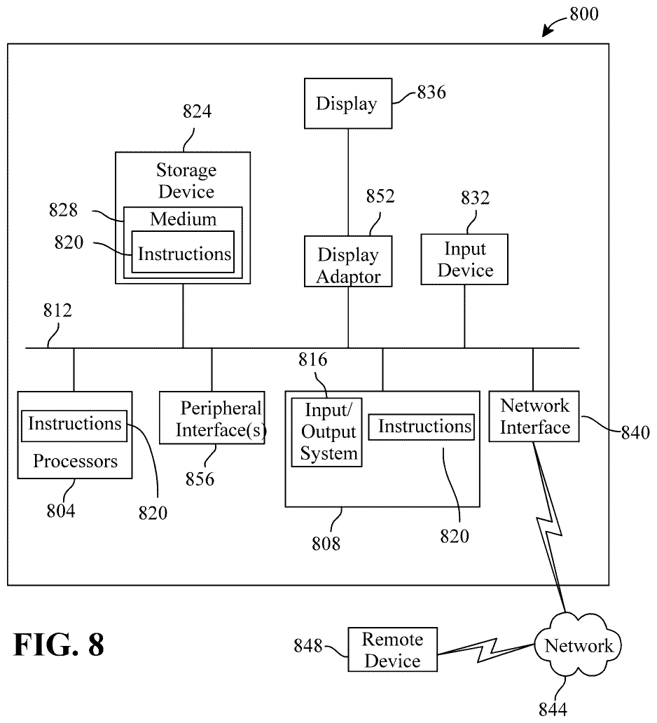

FIG. 8 shows a diagrammatic representation of one embodiment of a computing device in the exemplary form of a computer system 800 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 800 includes a processor 804 and a memory 808 that communicate with each other, and with other components, via a bus 812. Bus 812 may include any of several types of bus structures including, but not limited to, a memory bus, a memory controller, a peripheral bus, a local bus, and any combinations thereof, using any of a variety of bus architectures.

Processor 804 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 804 may be organized according to Von Neumann and/or Harvard architecture as a non-limiting example. Processor 804 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC)

Memory 808 may include various components (e.g., machine-readable media) including, but not limited to, a random-access memory component, a read only component, and any combinations thereof. In one example, a basic input/output system 816 (BIOS), including basic routines that help to transfer information between elements within computer system 800, such as during start-up, may be stored in memory 808. Memory 808 may also include (e.g., stored on one or more machine-readable media) instructions (e.g., software) 820 embodying any one or more of the aspects and/or methodologies of the present disclosure. In another example, memory 808 may further include any number of program modules including, but not limited to, an operating system, one or more application programs, other program modules, program data, and any combinations thereof.

Computer system 800 may also include a storage device 824. Examples of a storage device (e.g., storage device 824) include, but are not limited to, a hard disk drive, a magnetic disk drive, an optical disc drive in combination with an optical medium, a solid-state memory device, and any combinations thereof. Storage device 824 may be connected to bus 812 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 824 (or one or more components thereof) may be removably interfaced with computer system 800 (e.g., via an external port connector (not shown)). Particularly, storage device 824 and an associated machine-readable medium 828 may provide nonvolatile and/or volatile storage of machine-readable instructions, data structures, program modules, and/or other data for computer system 800. In one example, software 820 may reside, completely or partially, within machine-readable medium 828. In another example, software 820 may reside, completely or partially, within processor 804.

Computer system 800 may also include an input device 832. In one example, a user of computer system 800 may enter commands and/or other information into computer system 800 via input device 832. Examples of an input device 832 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 832 may be interfaced to bus 812 via any of a variety of interfaces (not shown) including, but not limited to, a serial interface, a parallel interface, a game port, a USB interface, a FIREWIRE interface, a direct interface to bus 812, and any combinations thereof. Input device 832 may include a touch screen interface that may be a part of or separate from display 836, discussed further below. Input device 832 may be utilized as a user selection device for selecting one or more graphical representations in a graphical interface as described above.

A user may also input commands and/or other information to computer system 800 via storage device 824 (e.g., a removable disk drive, a flash drive, etc.) and/or network interface device 840. A network interface device, such as network interface device 840, may be utilized for connecting computer system 800 to one or more of a variety of networks, such as network 844, and one or more remote devices 848 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 844, may employ a wired and/or a wireless mode of communication. In general, any network topology may be used. Information (e.g., data, software 820, etc.) may be communicated to and/or from computer system 800 via network interface device 840.

Computer system 800 may further include a video display adapter 852 for communicating a displayable image to a display device, such as display 836. Examples of a display device include, but are not limited to, a liquid crystal display (LCD), a cathode ray tube (CRT), a plasma display, a light emitting diode (LED) display, and any combinations thereof. Display adapter 852 and display 836 may be utilized in combination with processor 804 to provide graphical representations of aspects of the present disclosure. In addition to a display device, computer system 800 may include one or more other peripheral output devices including, but not limited to, an audio speaker, a printer, and any combinations thereof. Such peripheral output devices may be connected to bus 812 via a peripheral interface 856. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and apparatuses according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. An apparatus for bidirectional data integration, the apparatus comprising:
at least a processor; and
a memory communicatively connected to the at least a processor, wherein the memory contains instructions configuring the at least a processor to:
receive organoid data and omics data;
generate integrated data by integrating the organoid data and the omics data bidirectionally, wherein integrating the organoid data and the omics data bidirectionally comprises:
forward integration to correlate at least an organoid-derived parameter of the organoid data to molecular changes of the omics data; and
reverse integration to correlate at least an omics-derived parameter of the omics data to therapeutic agents of the organoid data;
generate a disease pathway as a function of the integrated data;
generate a peptide datum using a peptide machine-learning model as a function of the integrated data and the disease pathway;
determine an absorption, distribution, metabolism, excretion, and toxicity (ADMET) datum as a function of the peptide datum; and
generate a user interface displaying the integrated data, the peptide datum and the ADMET datum on a user device.

2. The apparatus of claim 1, wherein receiving the organoid data and the omics data comprises normalizing the organoid data and the omics data to remove noise, batch effects and biases.

3. The apparatus of claim 1, wherein receiving the organoid data and the omics data comprises extracting the at least an organoid-derived parameter and the at least an omics-derived parameter as a function of the organoid data and the omics data.

4. The apparatus of claim 1, wherein generating the peptide datum comprises generating the peptide datum as a function of affinity, stability, and therapeutic efficacy.

5. The apparatus of claim 1, wherein determining the ADMET datum comprises:
receiving user feedback for the displayed peptide datum and the ADMET datum; and
updating the peptide datum and the ADMET datum as a function of the user feedback.

6. The apparatus of claim 1, wherein determining the ADMET datum comprises updating the peptide datum as a function of the ADMET datum.

7. The apparatus of claim 1, wherein determining the ADMET datum comprises conducting in silico ADMET analysis to simulate pharmacokinetics and toxicity profiles of the peptide datum.

8. The apparatus of claim 1, wherein determining the ADMET datum comprises assessing toxicity of the peptide datum using organoid-based toxicity assays.

9. The apparatus of claim 8, wherein determining the ADMET datum comprises optimizing the peptide datum as a function of the ADMET datum and the toxicity of the peptide datum.

10. The apparatus of claim 1, wherein generating the peptide datum comprises:
generating peptide training data, wherein the peptide training data comprises exemplary integrated data and exemplary disease pathways correlated to exemplary peptide data;
training the peptide machine-learning model using the peptide training data;
inputting the integrated data into the trained peptide machine-learning model;
outputting the peptide datum using the trained peptide machine-learning model.

11. A method for bidirectional data integration, the method comprising:
receiving, using at least a processor, organoid data and omics data;
generating, using the at least a processor, integrated data by integrating the organoid data and the omics data bidirectionally, wherein integrating the organoid data and the omics data bidirectionally comprises:
forward integration to correlate at least an organoid-derived parameter of the organoid data to molecular changes of the omics data; and
reverse integration to correlate at least an omics-derived parameter of the omics data to therapeutic agents of the organoid data;
generating, using the at least a processor, a disease pathway as a function of the integrated data;
generating, using the at least a processor, a peptide datum using a peptide machine-learning model as a function of the integrated data and the disease pathway;
determining, using the at least a processor, an absorption, distribution, metabolism, excretion, and toxicity (ADMET) datum as a function of the peptide datum; and
generating, using the at least a processor, a user interface displaying the integrated data, the peptide datum and the ADMET datum on a user device.

12. The method of claim 11, wherein receiving the organoid data and the omics data comprises normalizing the organoid data and the omics data to remove noise, batch effects and biases.

13. The method of claim 11, wherein receiving the organoid data and the omics data comprises extracting the at least an organoid-derived parameter and the at least an omics-derived parameter as a function of the organoid data and the omics data.

14. The method of claim 11, wherein generating the peptide datum comprises generating the peptide datum as a function of affinity, stability, and therapeutic efficacy.

15. The method of claim 11, wherein determining the ADMET datum comprises:
receiving user feedback for the displayed peptide datum and the ADMET datum; and
updating the peptide datum and the ADMET datum as a function of the user feedback.

16. The method of claim 11, wherein determining the ADMET datum comprises updating the peptide datum as a function of the ADMET datum.

17. The method of claim 11, wherein determining the ADMET datum comprises conducting in silico ADMET analysis to simulate pharmacokinetics and toxicity profiles of the peptide datum.

18. The method of claim 11, wherein determining the ADMET datum comprises assessing toxicity of the peptide datum using organoid-based toxicity assays.

19. The method of claim 18, wherein determining the ADMET datum comprises optimizing the peptide datum as a function of the ADMET datum and the toxicity of the peptide datum.

20. The method of claim 11, wherein generating the peptide datum comprises:
generating peptide training data, wherein the peptide training data comprises exemplary integrated data and exemplary disease pathways correlated to exemplary peptide data;
training the peptide machine-learning model using the peptide training data;
inputting the integrated data into the trained peptide machine-learning model; and
outputting the peptide datum using the trained peptide machine-learning model.
